(19) United States
(12) Patent Application Publication
(10) Pub. No.: US 2025/0078249 A1
(43) Pub. Date: Mar. 6, 2025

(54) METHOD OF INSPECTING A MARK ENGRAVED ON A SEMICONDUCTOR PACKAGE

(71) Applicant: SAMSUNG ELECTRONICS CO., LTD., SUWON-SI, (KR)

(72) Inventors: Minwoo JEON, Suwon-si (KR); Kanggyune LEE, Suwon-si (KR); Hyunho CHU, Suwon-si (KR)

(21) Appl. No.: 18/753,198

(22) Filed: Jun. 25, 2024

(30) Foreign Application Priority Data
Sep. 4, 2023 (KR) 10-2023-0117233

(51) Int. Cl. G06T 7/00; G01N 21/95; G06T 7/13; G06T 7/136; G06T 7/64

(52) U.S. Cl. CPC G06T 7/001; G01N 21/9501; G06T 7/13; G06T 7/136; G06T 7/64; G06T 2207/30148; G06T 2207/30204

(57) ABSTRACT

A method of inspecting a mark of a semiconductor package includes: acquiring an original inspection image and an original reference image to determine whether the mark is defective; acquiring a target reference image and a target inspection image by converting each of the original reference image and the original inspection image into a binary image through thresholding; calculating an area matching rate by calculating a number of error pixels that have different brightness values from each other, among pixels of the target reference image that correspond to pixels of the target inspection image, and by using the number of error pixels relative to a number of total pixels of the target reference image; and calculating a shape matching rate by acquiring a first circularity of the target reference image and a second circularity of the target inspection image, and by comparing the first circularity with the second circularity.

### CROSS-REFERENCE TO RELATED APPLICATION

This application claims priority under 35 U.S.C. § 119 to Korean Patent Application No. 10-2023-0117233, filed on Sep. 4, 2023, in the Korean Intellectual Property Office, the disclosure of which is incorporated by reference herein in its entirety.

### TECHNICAL FIELD

Embodiments of the present inventive concept relate to a method of inspecting the appearance of a semiconductor package, and more specifically, to a method of inspecting a mark engraved on a semiconductor package.

### DISCUSSION OF THE RELATED ART

Machine vision technology, which has been under development, is technology for automatic inspection of semiconductor packages. Generally, in the automatic inspection of semiconductor packages, inspection items may be divided into an electrical characteristics and function inspection item and an appearance inspection item. In the appearance inspection item, whether a lead frame or a mark on a semiconductor package is defective is inspected.

In the appearance inspection item, positions, directions, distortions, scratches, missing, and breakage of various marks indicating information of semiconductor packages, such as a product name and a manufacturer name, are inspected. At the present time when semiconductor packages are gradually becoming smaller, it takes a lot of time and resources to deal with inspection items through visual inspection, and damage may occur due to the distribution of defective products due to misjudgment. Therefore, high performance vision inspection technology has recently been under development for the semiconductor mark inspection field.

However, because defects in marks exist in various forms and locations, strict and rapid inspection techniques are desirable, and, to this end, a quantitative evaluation criterion capable of measuring whether marks are defective is also desirable.

### SUMMARY

According to embodiments of the present inventive concept, a method of inspecting a mark of a semiconductor package includes: acquiring an original inspection image and an original reference image to determine whether the mark is defective; acquiring a target reference image and a target inspection image by converting each of the original reference image and the original inspection image into a binary image through thresholding; calculating an area matching rate by calculating a number of error pixels that have different brightness values from each other, among pixels of the target reference image that correspond to pixels of the target inspection image, and by using the number of error pixels relative to a number of total pixels of the target reference image; and calculating a shape matching rate by acquiring a first circularity of the target reference image and a second circularity of the target inspection image, and by comparing the first circularity with the second circularity.

According to embodiments of the present inventive concept, a method of inspecting a mark of a semiconductor package includes: acquiring an original inspection image to determine whether the mark is defective; acquiring an original reference image that is a reference for determining whether the mark is defective; converting each of the original reference image and the original inspection image into a binary image through thresholding; defining an outline of the original reference image, which was converted to the binary image, and an outline of the original inspection image, which was converted to the binary image; acquiring a target reference image by partitioning the original reference image; acquiring a target inspection image by extracting a part that corresponds to the target reference image from the original inspection image; calculating an area matching rate by calculating a number of error pixels that have different brightness values from each other among pixels of the target reference image that correspond to pixels of the target inspection image, and by using the number of error pixels relative to a number of total pixels of the target reference image; and calculating a shape matching rate by acquiring a first circularity of the target reference image and a second circularity of the target inspection image, and by comparing the first circularity with the second circularity.

According to embodiments of the present inventive concept, a method of inspecting a mark of a semiconductor package includes: acquiring an original inspection image to determine whether the mark engraved on a molding layer of the semiconductor package is defective; acquiring an original reference image that is a reference for determining whether the mark is defective; converting each of the original reference image and the original inspection image into a binary image through thresholding; defining an outline of the original reference image, which was converted to the binary image, and an outline of the original inspection image, which was converted to the binary image, and configuring the original reference image as a plurality of unit reference areas formed from dividing the original reference image with an outline as a boundary; acquiring a preliminary reference image including one unit reference area among the plurality of unit reference areas by partitioning the original reference image; acquiring a preliminary inspection image by extracting a part corresponding to the preliminary reference image from the original inspection image; acquiring a target reference image and a target inspection image by respectively dividing the preliminary reference image and the preliminary inspection image; equalizing a pixels per inch (PPI) of the target reference image to be equal to a PPI of the target inspection image, and equalizing a size of the target reference image to a size of the target inspection image; calculating an area matching rate by calculating a number of error pixels that have different brightness values from each other among pixels of the target reference image that correspond to pixels of the target inspection image, and by using the number of error pixels relative to a number of total pixels of the target reference image; and calculating a shape matching rate by acquiring a first circularity of the target reference image and a second circularity of the target inspection image, and by comparing the first circularity with the second circularity.

### BRIEF DESCRIPTION OF THE DRAWINGS

The above and other aspects of the present inventive concept will become more apparent by describing in detail embodiments thereof, with reference to the accompanying drawings, in which:

FIGS. 1 and 2 are flowcharts of a semiconductor package mark inspection method according to embodiments the present inventive concept;

FIG. 3 is a diagram illustrating an operation of acquiring an original inspection image;

FIG. 4 is a diagram illustrating acquired original reference images and original inspection images;

FIG. 5 is a diagram illustrating an original reference image and an original inspection image converted into a binary image by thresholding the original reference image and the original inspection image;

FIG. 6 is a diagram illustrating a method of defining an outline of an original inspection image;

FIG. 7 is a diagram illustrating a process of acquiring a plurality of preliminary reference images by partitioning an original reference image;

FIG. 8 is a diagram illustrating a process of acquiring a preliminary inspection image by extracting a part corresponding to a preliminary reference image from an original reference image;

FIG. 9 is a diagram illustrating a process of acquiring target reference images and target inspection images by dividing a preliminary reference image and a preliminary inspection image, respectively;

FIGS. 10 and 11 are diagrams illustrating a process of calculating an area matching rate by overlapping a target reference image and a target inspection image;

FIG. 12 is a diagram illustrating a process of calculating a shape matching rate, and FIG. 13 is a diagram illustrating results of calculating the shape matching rate;

FIG. 14 is a table showing results according to the semiconductor package mark inspection method; and

FIG. 15 is a schematic block diagram of a mark inspection device according to embodiments of the present inventive concept.

### DETAILED DESCRIPTION OF THE EMBODIMENTS

Hereinafter, embodiments of the present inventive concept will be described in detail with reference to the accompanying drawings. However, the present inventive concept is limited not to the embodiments described below and may be embodied in various other forms.

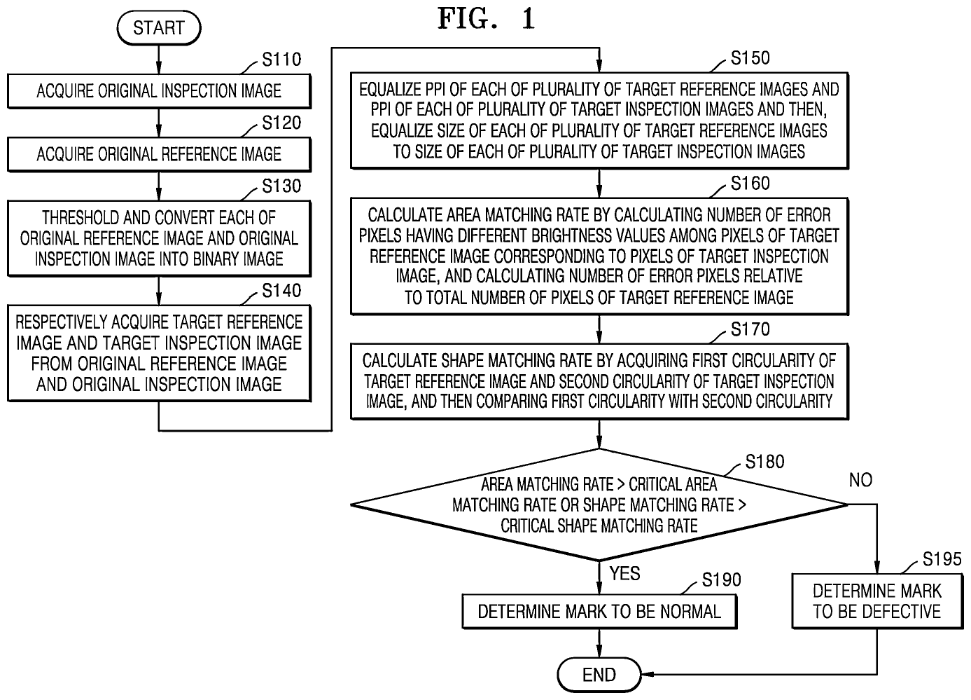

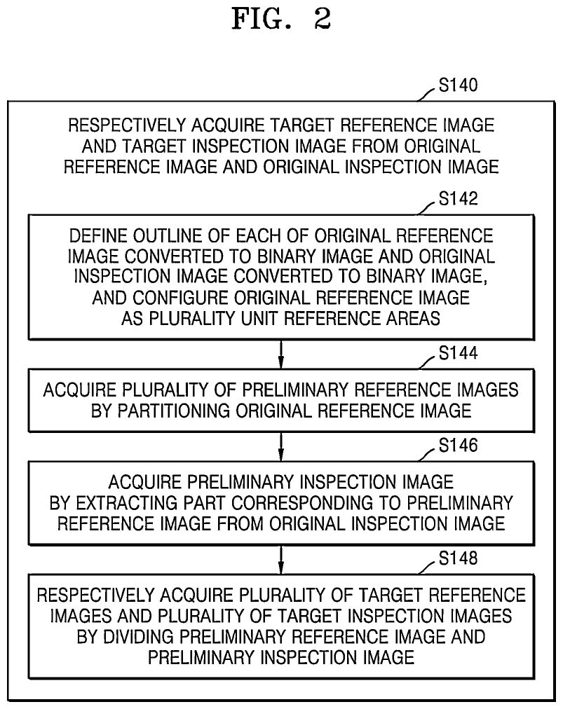

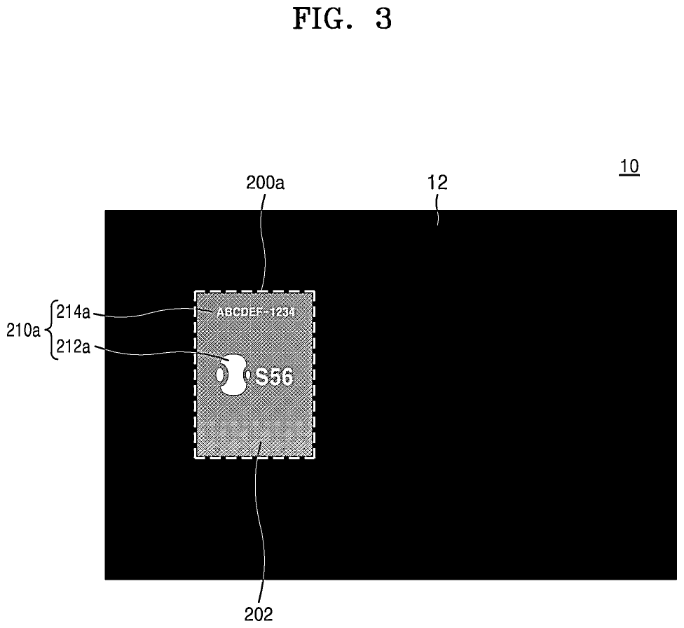

FIGS. 1 and 2 are flowcharts of a semiconductor package mark inspection method according to embodiments the present inventive concept. Specifically, FIG. 1 is a flowchart sequentially showing the semiconductor package mark inspection method, and FIG. 2 is a detailed flowchart showing an operation of acquiring an original reference image and a target reference image and a target inspection image from the original inspection image. In addition, FIGS. 3 to 14 are diagrams illustrating in detail a semiconductor package mark inspection method. Hereinafter, the semiconductor package mark inspection method according to embodiments of the present inventive concept will be described with reference to FIGS. 3 to 14 together with FIGS. 1 and 2.

A semiconductor product to which the semiconductor package mark inspection method according to embodiments of the present inventive concept is applied may be a semiconductor chip package in which a semiconductor integrated circuit chip manufactured in a wafer state is separated into individual chips after undergoing an electrical characteristic inspection and assembled in a package state. In addition, a mark 210a (see FIG. 3) is a character string or a barcode recorded on a molding layer 202 (see FIG. 3) of a semiconductor package.

The semiconductor package mark inspection method according to embodiments of the present inventive concept may be performed in an appearance inspection operation after completing a series of package assembly processes, or in the final inspection and packaging operation before product shipment.

FIG. 3 is a diagram illustrating an operation of acquiring an original inspection image.

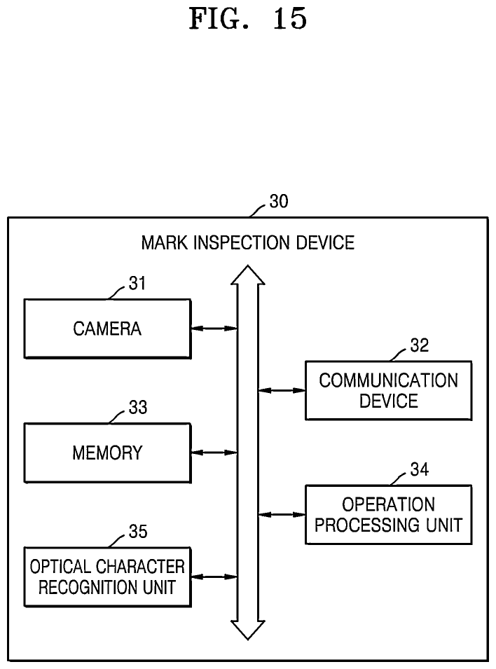

Referring to FIG. 3 together with FIG. 1, the semiconductor package mark inspection method according to embodiments of the present inventive concept may include operation S110 of acquiring an original inspection image 200a. A mark inspection device 30 (see FIG. 15) may capture a semiconductor package image by using a camera 31 (see FIG. 15). At this time, a captured image 10 may include a noise area 12 and an original inspection image 200a including an image of a semiconductor package. The original inspection image 200a may include an image of the molding layer 202 of the semiconductor package and an image of the mark 210a engraved on the molding layer 202. The mark 210a may include a product name mark 212a and a serial number mark 214a engraved in the center of the molding layer 202 of the semiconductor package. However, the present inventive concept is not limited thereto, and the mark 210a may include more various series of character strings according to a semiconductor package product.

In operation S110 of acquiring the original inspection image 200a, a process of removing the noise area 12 from the image 10 captured by using the camera 31 (see FIG. 15), and separately classifying only the original inspection image 200a is performed. At this time, the original inspection image 200a may be a reference image for determining whether the mark 210a engraved on the molding layer 202 of the semiconductor package is defective.

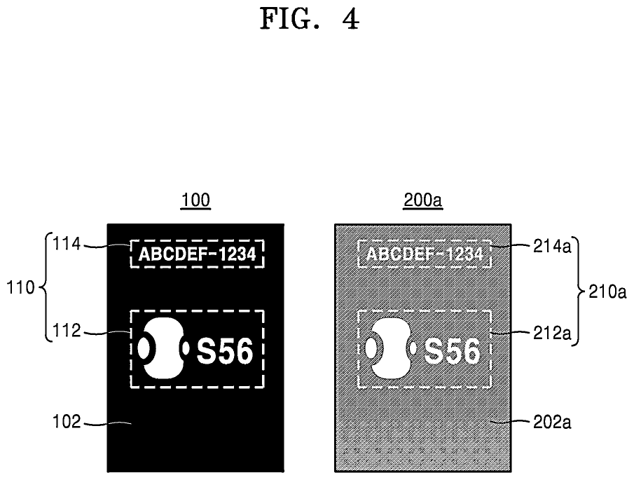

FIG. 4 is a diagram illustrating acquired original reference images and original inspection images.

Referring to FIG. 4 together with FIG. 1, the semiconductor package mark inspection method according to embodiments of the present inventive concept may include operation S120 of acquiring an original reference image 100. The original reference image 100 may be an image stored in a memory 33 (see FIG. 15) of the mark inspection device 30 (see FIG. 15).

According to an embodiment of the present inventive concept, the original reference image 100 may be a reference image for determining whether the mark 210a engraved on the molding layer 202 of the original inspection image 200a is defective. The original reference image 100 stored in the memory 33 (see FIG. 15) may be an image having a semiconductor package shape that is substantially the same as the original inspection image 200a.

Similar to the original inspection image 200a, the original reference image 100 may include the molding layer 102 and an image of a mark 110 that is engraved on the molding layer 102. At this time, a product name mark 112 may be engraved on the central portion of the molding layer 102 of the original reference image 100, and a serial number mark 114 may be engraved on an upper portion of the molding layer 102. The product name mark 112 of the original reference image 100 may correspond to the product name mark 212a of the original inspection image 200a, and the serial number mark 114 of the original reference image 100 may correspond to the product name mark 214a of the original inspection image 200a.

The original reference image 100 and the original inspection image 200a may be black and white images. The original reference image 100 may be divided into a bright area and a dark area and divided into a foreground and a background. At this time, the mark 110 of the original reference image 100 may be the bright area, and the molding layer 102 of the original reference image 100 may be the dark area. In contrast, the original inspection image 200a may include pixels having a pixel brightness of about 0 to about 255. Therefore, unlike the original reference image 100 that is divided into the bright area and the dark area, the original inspection image 200a may be a black and white image having multi-layered brightness. However, the present inventive concept is not necessarily limited thereto, and, similar to the original inspection image 200a, the original reference image 100 may be a black and white image including pixels having a pixel brightness of about 0 to about 255 and having multi-layered brightness according to an embodiment of the present inventive concept.

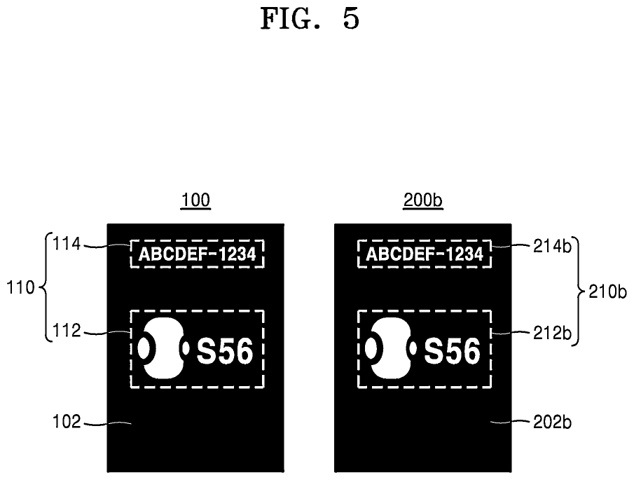

FIG. 5 is a diagram showing the original reference image 100 and an original inspection image 200b converted into a binary image by thresholding the original reference image 100 and the original inspection image 200a.

Referring to FIG. 5 together with FIG. 1, the semiconductor package mark inspection method according to embodiments of the present inventive concept may include operation S130 of thresholding and converting each of the original reference image 100 and the original inspection image 200b into the binary image.

Referring to FIG. 5, the original inspection image 200b converted to the binary image may be a black and white image that is divided into a bright area and a dark area and divided into a foreground and a background, unlike the original inspection image 200a shown in FIG. 4. At this time, a mark 210b of the original inspection image 200b may be the bright area, and a molding layer 202b of the original inspection image 200b may be the dark area. In embodiments of the present inventive concept, because the original reference image 100 is already divided into the bright area and the dark area, in this case, a thresholding process might not be performed on the original reference image 100. However, similar to the original inspection image 200a (see FIG. 4) before undergoing the thresholding process, the original reference image 100 may also be the black and white image including pixels having a pixel brightness of about 0 to about 255 and having multi-layered brightness according to an embodiment of the present inventive concept. Therefore, in this case, the thresholding process may be performed on the original reference image 100.

Thresholding is the process of converting pixels that have a pixel brightness of an integer in a range of about 0 to about 255 into a binary image having only values of 0 and 1. Through the thresholding process, an object in an image may be separated from the background. In the thresholding process, for example, a value having a pixel brightness of 180 or more may be treated as 1, and a value having a pixel brightness less than 180 may be treated as 0. However, 180 that is the reference of the pixel brightness stated above is only an example, and the reference of the pixel brightness may vary according to an embodiment of the present inventive concept.

In comparison with FIGS. 4 and 5, an area of the molding layer 202a of the original inspection image 200a before the thresholding process may include pixels having multi-layered brightness, but an area of the molding layer 202b of the original inspection image 200b after the thresholding process may include pixels having a brightness of 0.

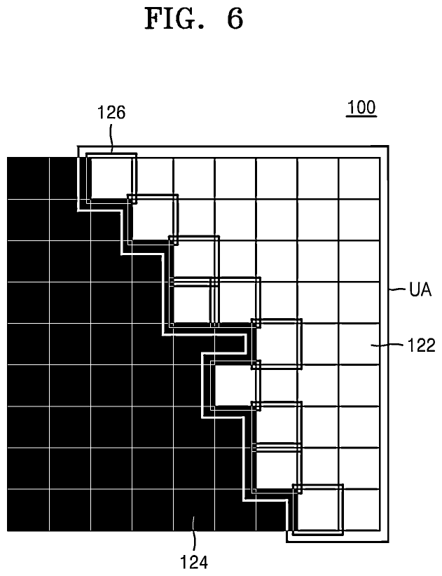

FIG. 6 is a diagram illustrating a method of defining an outline of the original reference image 100. Specifically, FIG. 6 shows enlarged pixels of the original reference image 100.

Referring to FIG. 6 together with FIGS. 1 and 2, the semiconductor package mark inspection method according to embodiments of the present inventive concept may include operation S140 of respectively acquiring a target reference image and a target inspection image from the original reference image 100 and an original inspection image. At this time, operation S140 of respectively acquiring the target reference image and the target inspection image from the original reference image 100 and the original inspection image may include operation S142 of defining an outline of each of the original reference image 100 that is converted to a binary image and the original inspection image that is converted to a binary image, and configuring the original reference image 100 as a plurality unit reference areas.

As shown in FIG. 6, the original reference image 100 includes four pixels arranged in a horizontal direction in one pixel and four pixels arranged in a diagonal direction with respect to the horizontal direction. At this time, the original reference image 100, which is the binary image, may include pixels 122 having a pixel brightness of 1 and pixels 124 having a pixel brightness of 0. To define the outline of the original reference image 100, a task of selecting pixels to be defined as the outline should be performed. When any of the four pixels arranged in the horizontal direction with respect to the pixel 122 having a pixel brightness of 1 is the pixel 124 having a pixel brightness of 0, the pixel 122 having a pixel brightness of 1 may be an outline pixel 126. For example, the outline pixel 126 may be the outermost pixel among the pixels 122 having a pixel brightness of 1. The outline pixels 126 may be arranged to be continuously connected to each other. To be arranged to be continuously connected to each other, among the four pixels arranged in the horizontal direction or among the four pixels arranged in the diagonal direction with respect to the horizontal direction in the outline pixel 126, at least one other outline pixel 126 must be arranged. The outline pixels 126 and the pixels 122 having a pixel brightness of 1 surrounded by the outline pixels 126 may be a unit area (UA).

FIG. 6 illustrates the process of defining the outline of the original reference image 100 and configuring the original reference image 100 into a plurality of unit areas UA, but this process is limited to the original reference image 100, and the outline of the original inspection image 200b (see FIG. 5) may be defined in the same way.

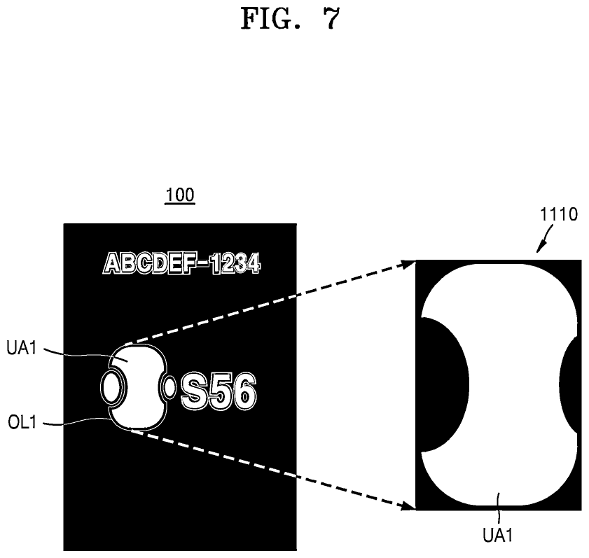

FIG. 7 is a diagram illustrating a process of acquiring a plurality of preliminary reference images 1110 by partitioning the original reference image 100.

Referring to FIG. 7 together with FIG. 2, the semiconductor package mark inspection method according to embodiments of the present inventive concept may include operation S140 of respectively acquiring a target reference image and a target inspection image from the original reference image 100 and an original inspection image. At this time, operation S140 of respectively acquiring the target reference image and the target inspection image from the original reference image 100 and the original inspection image may include operation S144 of acquiring the plurality of preliminary reference images 1110 by partitioning the original reference image 100.

The original reference image 100 may include a plurality of unit areas UA1 partitioned by an outline OL1. The plurality of preliminary reference images 1110 may be acquired from the original reference image 100, and each of the plurality of preliminary reference images 1110 may include one unit area UA1. The unit area UA1 may be a set of pixels having a pixel brightness value of 1, and the unit area UA1 may be surrounded by a continuously connected outline OL1.

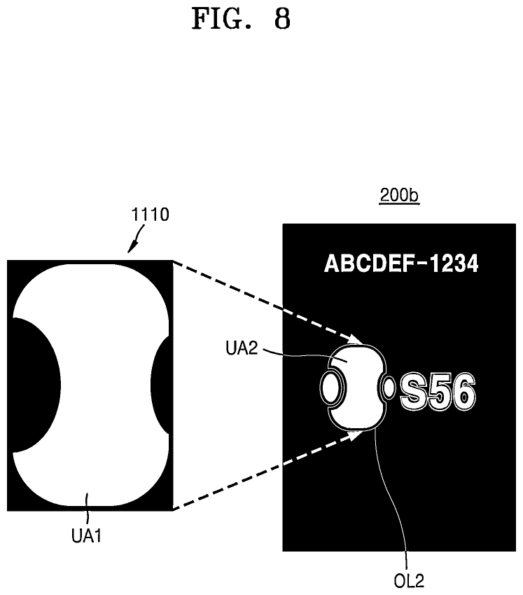

FIG. 8 is a diagram illustrating a process of acquiring a preliminary inspection image by extracting a part corresponding to the preliminary reference image 1110 from an original reference image.

Referring to FIG. 8 together with FIG. 2, the semiconductor package mark inspection method according to embodiments of the present inventive concept may include operation S140 of respectively acquiring a target reference image and a target inspection image from the original reference image and the original inspection image 200b. At this time, operation S140 of acquiring the target reference image and the target inspection image may include operation S146 of acquiring the preliminary inspection image by extracting a part corresponding to the preliminary reference image 1110 from the original inspection image 200b.

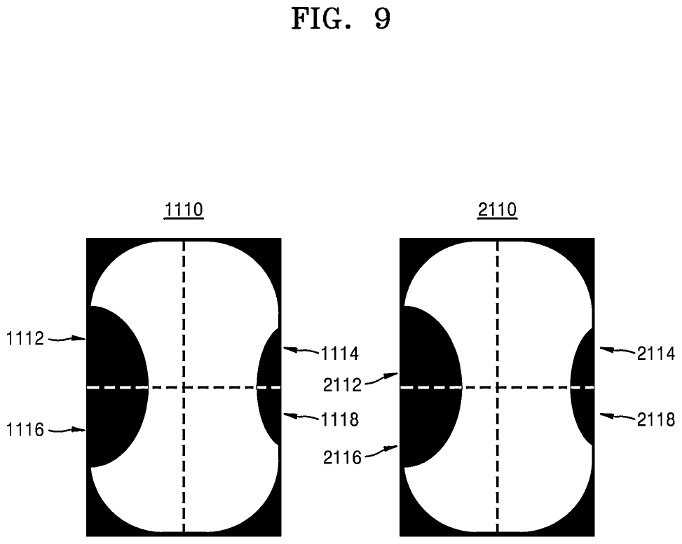

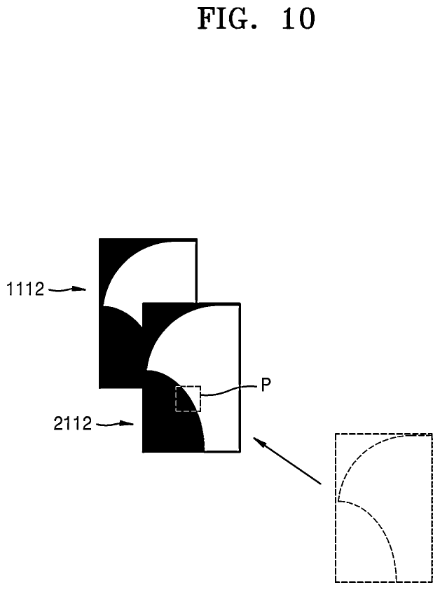

The original inspection image 200b that is converted into a binary image may include a plurality of unit areas UA2 that are formed from partitioning the original inspection image 200b with an outline OL2. The preliminary reference image 1110 may include one unit area UA1. The unit area UA2 corresponding to the unit area UA1 that is included in the preliminary reference image 1110 may be detected by scanning the original inspection image 200b. After detecting the unit area UA2 of the original inspection image 200b that corresponds to the unit area UA1 of the preliminary reference image 1110, a preliminary inspection image 2110 (see FIG. 9) including the unit area UA2 of the original inspection image 200b may be acquired.

FIG. 9 is a diagram illustrating a process of acquiring a plurality of target reference images 1112, 1114, 1116, and 1118 and a plurality of target inspection images 2112, 2114, 2116, and 2118 by dividing the preliminary reference image 1110 and a preliminary inspection image 2110, respectively.

Referring to FIG. 9 together with FIG. 2, the semiconductor package mark inspection method according to the inventive concept may include operation S140 of acquiring the plurality of target reference images 1112, 1114, 1116, and 1118 and the plurality of target inspection images 2112, 2114, 2116, and 2118 from an original reference image and an original inspection image, respectively. Further, operation S140 of acquiring the plurality of target reference images 1112, 1114, 1116, and 1118 and the plurality of target inspection images 2112, 2114, 2116, and 2118 may include operation S148 of acquiring the plurality of target reference images 1112, 1114, 1116, and 1118 and the plurality of target inspection images 2112, 2114, 2116, and 2118 by dividing the preliminary reference image 1110 and the preliminary inspection image 2110, respectively.

According to an embodiment of the present inventive concept, the preliminary reference image 1110 may be divided into the plurality of target reference images 1112, 1114, 1116, and 1118, and the preliminary inspection image 2110 may be divided into the plurality of target inspection images 2112, 2114, 2116, and 2118. The plurality of target inspection images 2112, 2114, 2116, and 2118 are images that are to be measured for an area matching rate and a shape matching rate so as to determine whether a mark of a semiconductor package is defective. The plurality of target reference images 1112, 1114, 1116, and 1118 are reference images for determining whether the mark is defective, and are images that are to be measured for the area matching rate and the shape matching rate.

According to an embodiment of the present inventive concept, the preliminary reference image 1110 may be divided into the four target reference images 1112, 1114, 1116, and 1118. For example, the plurality of target reference images 1112, 1114, 1116, and 1118 may be formed by dividing the preliminary reference image 1110 with a horizontal cutting line that passes through the center of the preliminary reference image 1110 and a vertical cutting line that passes through the center of the preliminary reference image 1110. However, this is only an embodiment of the present inventive concept, and the preliminary reference image 1110 may be divided into N target reference images as desired by an inspector according to an embodiment of the present inventive concept.

Likewise, the preliminary inspection image 2110 may be divided into the four target inspection images 2112, 2114, 2116, and 2118. For example, the plurality of target inspection images 2112, 2114, 2116, and 2118 may be formed by dividing the preliminary inspection image 2110 with a horizontal cutting line that passes through the center of the preliminary inspection image 2110 and a vertical cutting line that passes through the center of the preliminary inspection image 2110. However, the present inventive concept is not limited thereto, and the preliminary inspection image 2110 may be divided into N target inspection images as desired by the inspector according to an embodiment of the present inventive concept. However, the preliminary inspection image 2110 might not be divided independently from the preliminary reference image 1110. For example, the preliminary inspection image 2110 may depend on shapes and patterns into which the preliminary reference image 1110 is divided, and accordingly may be divided into the N target inspection images. When operation S148 of acquiring the plurality of target reference images 1112, 1114, 1116, and 1118 and the plurality of target inspection images 2112, 2114, 2116, and 2118 by dividing the preliminary reference image 1110 and the preliminary inspection image 2110, respectively, ends, operation S140 of respectively acquiring the plurality of target reference images 1112, 1114, 1116, and 1118 and the plurality of target inspection images 2112, 2114, 2116, and 2118 from the original reference image 100 and the original inspection image 200b converted into a binary image ends.

According to an embodiment of the present inventive concept, the semiconductor package mark inspection method may include operation S150 of equalizing pixels per inch (PPI) of each of the plurality of target reference images 1112, 1114, 1116, and 1118 to PPI of each of the plurality of target inspection images 2112, 2114, 2116, and 2118 and then, equalizing the size of each of the plurality of target reference images 1112, 1114, 1116, and 1118 to the size of each of the plurality of target inspection images 2112, 2114, 2116, and 2118. At this time, the PPI of each of the plurality of target reference images 1112, 1114, 1116, and 1118 may be the same as the PPI of each of the plurality of target inspection images 2112, 2114, 2116, and 2118. Thereafter, when one of the plurality of target reference images 1112, 1114, 1116, and 1118 overlaps one of the plurality of target inspection images 2112, 2114, 2116, and 2118, the sizes of the plurality of target reference images 1112, 1114, 1116, and 1118 and the sizes of the plurality of target inspection images 2112, 2114, 2116, and 2118 may be adjusted such that the size of each of the plurality of target reference images 1112, 1114, 1116, and 1118 is the same as the size of each of the plurality of target inspection images 2112, 2114, 2116, and 2118.

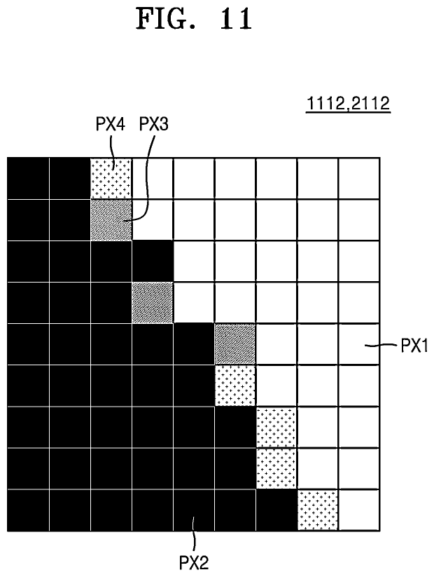

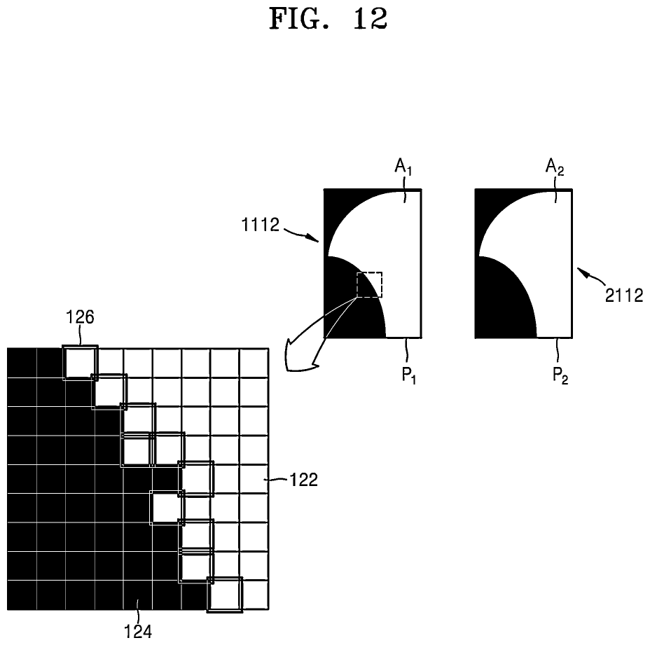

FIGS. 10 and 11 are diagrams illustrating a process of calculating an area matching rate by overlapping the target reference image 1112 and the target inspection image 2112.

Referring to FIGS. 10 and 11 together with FIG. 1, the semiconductor package mark inspection method according to an embodiment of the present inventive concept may include operation S160 of calculating the area matching rate by overlapping the target reference image 1112 and the target inspection image 2112, by calculating the number of error pixels having different brightness values among pixels of the target reference image 1112 corresponding to pixels of the target inspection image 2112, and by calculating the number of error pixels relative to the total number of the pixels of the target reference image 1112. FIG. 11 is an enlarged view of area P of FIG. 10 after overlapping the target reference image 1112 and the target inspection image 2112. The target reference image 1112 stated below is one of the plurality of target reference images 1112, 1114, 1116, and 1118 shown in FIG. 9, and the target inspection image 2112 stated below is one of the target inspection images 2112, 2114, 2116, and 2118 shown in FIG. 9.

The area matching rate may be defined as 100% minus an area error rate. At this time, the area error rate may be defined as a value expressed as a percentage of the number of error pixels relative to the total number of pixels of the target reference image 1112.

Referring to FIG. 11, the target inspection image 2112, which is converted into a binary image, and the target reference image 1112 may include a pixel having a pixel brightness of 0 and a pixel having a pixel brightness of 1, respectively. When the target reference image 1112 and the target inspection image 2112 overlap each other, in a case where the pixels of the target reference image 1112 and the pixels of the target inspection image 2112 corresponding thereto both have the pixel brightness of 1, the pixels may be defined as first pixels PX1. The first pixel PX1 refers to a pixel of the target inspection image 2112 in which a mark is accurately implemented compared to the target reference image 1112.

In addition, when the target reference image 1112 and the target inspection image 2112 overlap each other, in a case where the pixels of the target reference image 1112 and the pixels of the target inspection image 2112 corresponding thereto both have a pixel brightness of 0, the pixels may be defined as second pixels PX2. Similar to the first pixel PX1, the second pixel PX2 also refers to a pixel of the target inspection image 2112 in which a mark is accurately implemented compared to the target reference image 1112.

In addition, when the target reference image 1112 and the target inspection image 2112 overlap each other, in a case where the pixels of the target reference image 1112 have the pixel brightness of 1, and the pixels of the target inspection image 2112 corresponding to the target reference image 1112 have the pixel brightness of 0, the pixels may be defined as third pixels PX3. For example, in this case, the pixel of the target reference image 1112 having the pixel brightness of 1 corresponds to the pixels of the target inspection image 2112 having the pixel brightness of 0. The third pixel PX3 is a pixel of the target inspection image 2112 in which a mark is not accurately implemented compared to the target reference image 1112, and is defined as an error pixel.

In addition, when the target reference image 1112 and the target inspection image 2112 overlap each other, in a case where the pixels of the target reference image 1112 have the pixel brightness of 0, and the pixels of the target inspection image 2112 corresponding to the target reference image 1112 have the pixel brightness of 1, the pixels may be defined as fourth pixels PX4. For example, in this case, the pixel of the target reference image 1112 having the pixel brightness of 0 corresponds to the pixels of the target inspection image 2112 having the pixel brightness of 1. The fourth pixel PX4 is also a pixel of the target inspection image 2112 in which a mark is not accurately implemented compared to the target reference image 1112, and is defined as an error pixel.

Hereinafter, a method of calculating the area matching rate is described with reference to FIG. 11. In light of the example shown in FIG. 11, the area P is a 9×9 arrangement of pixels including a total of 81 pixels. Among the 81 pixels, the number of third pixels PX3 defined as error pixels is 3, and the number of fourth pixels PX4 defined as error pixels is 5. Therefore, the total number of error pixels is 8. In this case, because the area error rate of the area P is a value expressed as a percentage of the number of error pixels compared to the total number of pixels of the target reference image 1112, the area error rate may be 8/81, with is approximately 9.87%. Therefore, 90.13%, which is 9.87% subtracted from 100%, is the area matching rate of the area P.

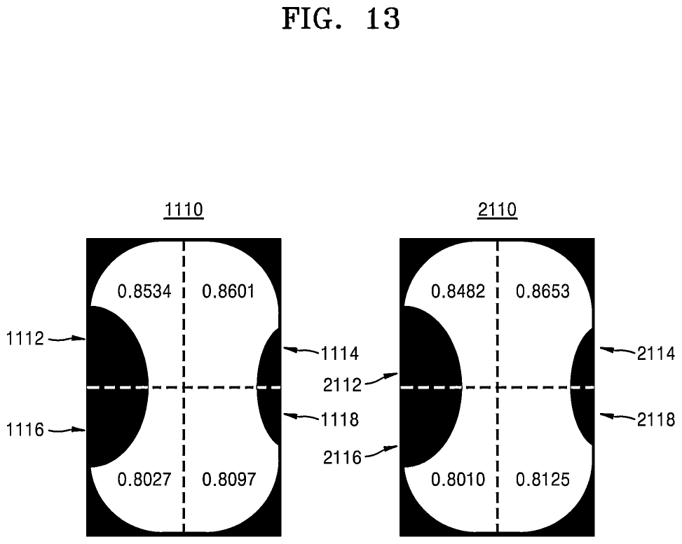

FIG. 12 is a diagram illustrating a process of calculating a shape matching rate, and FIG. 13 is a diagram illustrating results of calculating the shape matching rate.

Referring to FIGS. 12 and 13 together with FIG. 1, the semiconductor package mark inspection method according to embodiments of the present inventive concept may include operation S170 of calculating the shape matching rate by acquiring a first circularity of the target reference image 1112 and a second circularity of the target inspection image 2112, and then comparing the first circularity with the second circularity.

The shape matching rate may be expressed as the second circularity of the target inspection image 2112 compared to the first circularity of the target reference image 1112. Circularity is an indicator of the relationship between the circumference and area of a figure, and in general, the closer the figure is to the circle, the higher the circularity. Circularity may be mainly used to calculate an outline of a figure or analyze a shape of the shape.

FIG. 12 shows the target reference image 1112, the target inspection image 2112, and an enlarged image of the target reference image 1112. FIG. 13 shows the first circularity of each of the four target reference images 1112, 1114, 1116, and 1118 that are included in the preliminary reference image 1110 and the second circularity of each of the four target inspection images 2112, 2114, 2116, and 2118 that are included in the preliminary inspection image 2110.

According to an embodiment of the present inventive concept, in operation of calculating the first circularity and the second circularity, the first circularity is derived by performing an operation according to Equation 1 below, and the second circularity is derived by performing an operation according to Equation 2 below.

$${C}_{1} = 4 π \times \frac{{A}_{1}}{{P}_{1}^{2}} \qquad [ Equation 1 ]$$

$${C}_{2} = 4 π \times \frac{{A}_{2}}{{P}_{2}^{2}} \qquad [ Equation 2 ]$$

In Equation 1 above, C₁ denotes the first circularity, A₁ denotes the total area of pixels having a high brightness value of the target reference image 1112, and P₁ denotes a length of an outline of the target reference image 1112. In addition, in Equation 2 above, C₂ denotes the second circularity, A₂ denotes the total area of pixels having a high brightness value of the target inspection image 2112, and P₂ denotes a length of an outline of the target inspection image 2112.

According to an embodiment of the present inventive concept, A₁ denotes the total sum of areas of pixels 122 having a pixel brightness value of 1 in the target reference image 1112. In addition, P₁ may be the sum of edges of outline pixels 126 contacting pixels 124 having a pixel brightness value of 0. For example, in FIG. 12, the total number of outline pixels 126 is 11, and the total number of edges of the outline pixels 126 contacting the pixels 124 having the pixel brightness value of 0 is 16. Therefore, P₁ denotes the sum of lengths of the total of 16 edges.

The closer the shape shown in the target reference image 1112 is to the circle, the closer the circularity is to 1. As used herein, the shape shown in the target reference image 1112 refers to the shape of a set of pixels 122 having the pixel brightness value of 1.

FIG. 13 shows the first circularities of the four target reference images 1112, 1114, 1116, and 1118 of the preliminary reference image 1110 and the second circularities of the four target inspection images 2112, 2114, 2116, and 2118 of the preliminary inspection image 2110. Hereinafter, the method of calculating the shape matching rate through the first circularity and the second circularity is described.

The first circularity of the first target reference image 1112 is 0.8534, and the second circularity of the first target inspection image 2112 is 0.8482. Accordingly, the shape matching rate of the first target inspection image 2112 is 99.39% as a percentage of 0.8482/0.8534. The first circularity of the second target reference image 1114 is 0.8601, and the second circularity of the second target inspection image 2114 is 0.8653. Accordingly, the shape matching rate of the second target inspection image 2114 is 99.40% as a percentage of 0.8601/0.8653. The first circularity of the third target reference image 1116 is 0.8027, and the second circularity of the third target inspection image 2116 is 0.8010. Accordingly, the shape matching rate of the third target inspection image 2116 is 99.79% as a percentage of 0.8010/0.8027. The first circularity of the fourth target reference image 1118 is 0.8097, and the second circularity of the fourth target inspection image 2118 is 0.8125. Accordingly, the shape matching rate of the fourth target inspection image 2118 is 99.66% as a percentage of 0.8097/0.8125.

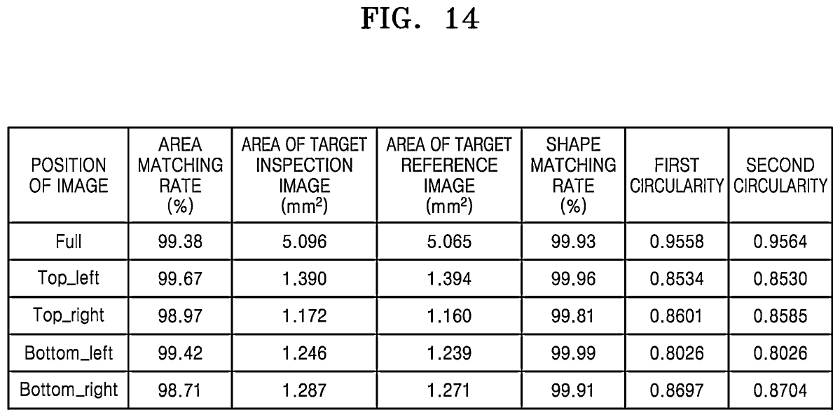

FIG. 14 is a table showing results according to the semiconductor package mark inspection method.

Referring to FIG. 14 together with FIG. 1, the semiconductor package mark inspection method according to embodiments of the present inventive concept may include operation S180 of calculating a shape matching rate by acquiring a first circularity of a target reference image and a second circularity of a target inspection image, and then comparing the first circularity with the second circularity. Thereafter, the semiconductor package mark inspection method according to embodiments of the present inventive concept may further include operation S190 of determining a mark to be normal when an area matching rate is greater than a preset critical area matching rate or when the shape matching rate is greater than a preset critical shape matching rate. The semiconductor package mark inspection method according to embodiments of the present inventive concept may further include operation S195 of determining a mark to be defective when the area matching rate is less than the preset critical area matching rate or the shape matching rate is less than the preset critical shape matching rate.

According to an embodiment of the present inventive concept, the area matching rate and the shape matching rate of each of a plurality of target inspection images may be calculated through a series of operations in the semiconductor package mark inspection method. Referring to the table shown in FIG. 14, the semiconductor package mark inspection method may determine whether the mark of a semiconductor package is defective or normal by respectively comparing the area matching rate and the shape matching rate of each of the plurality of target inspection images with the preset critical area matching rate and the preset critical shape matching rate.

FIG. 15 is a schematic block diagram of a mark inspection device 30 according to embodiments of the present inventive concept.

Referring to FIG. 15, the mark inspection device 30 may include a camera 31, a communication device 32, a memory 33, an operation processing unit 34 (e.g., a processor or operation processing circuit), and an optical character recognition unit 35 (e.g., an optical character recognition circuit). However, the components included in the mark inspection device 30 are not necessarily limited to the components listed above, and the mark inspection device 30 may include various components for inspecting a mark of a semiconductor package.

According to an embodiment of the present inventive concept, the camera 31 may be configured to capture a mark engraved on a molding layer of the semiconductor package by capturing the semiconductor package. The communication device 32 may provide network communication to the mark inspection device 30. A network may be a wired network or a wireless network such as radio, cellular, satellite, broadcast, etc. The mark inspection device 30 may communicate with an automated optical inspection (AOI) system through the communication device 32. In an embodiment of the present inventive concept, the mark inspection device 30 may be an electrical device installed with an image processing program, such as a computer, a smartphone, a personal computer, a server, etc.

According to an embodiment of the present inventive concept, the camera 31 may capture a mark character of the semiconductor package that is to be inspected, and a mark character image captured by the camera 31 may be recognized as a character string by the optical character recognition unit 35. Subsequently, the operation processing unit 34 may sequentially compare the recognized character string with an inspection reference value character string that is stored in the memory 33 for each area to determine whether the mark is normal or defective.

According to an embodiment of the present inventive concept, the memory 33 may include, for example, flash memory, hard disk drive (HDD), solid state drive (SSD), Dynamic Random Access Memory (DRAM), Static Random Access Memory (SRAM), etc. The optical character recognition unit 35 may include, for example, an image scanner, optical character recognition (OCR) software using OCR technology, a text segmentation system that performs a function of identifying and separating a character area in an image, a character classification algorithm that identifies and classifies an extracted character, a character correction and post-processing system that performs a function of correcting a recognized character after OCR and correcting an error in the character, etc. The operation processing unit 34 may include, for example, a central processing unit (CPU), a graphics processing unit (GPU), a vector processor, a quantum operation processing unit, an embedded operation processing unit, etc.

While the present inventive concept has been described with reference to example embodiments thereof, it will be understood by those of ordinary skill in the art that various changes in form and details may be made thereto without departing from the spirit and scope of the present inventive concept.

What is claimed is:

1. A method of inspecting a mark of a semiconductor package, the method comprising:
acquiring an original inspection image and an original reference image to determine whether the mark is defective;
acquiring a target reference image and a target inspection image by converting each of the original reference image and the original inspection image into a binary image through thresholding;
calculating an area matching rate by calculating a number of error pixels that have different brightness values from each other, among pixels of the target reference image that correspond to pixels of the target inspection image, and by using the number of error pixels relative to a number of total pixels of the target reference image; and
calculating a shape matching rate by acquiring a first circularity of the target reference image and a second circularity of the target inspection image, and by comparing the first circularity with the second circularity.

2. The method of claim 1, wherein the first circularity is determined according to Equation 1 below, and the second circularity is determined according to Equation 2 below,
$${C}_{1} = 4 π \times \frac{{A}_{1}}{{P}_{1}^{2}} \qquad [ Equation 1 ]$$
$${C}_{2} = 4 π \times \frac{{A}_{2}}{{P}_{2}^{2}} \qquad [ Equation 2 ]$$
in Equation 1 above, C₁ denotes the first circularity, A₁ denotes a total area of pixels having a brightness value of 1 in the target reference image including pixels having a brightness value of 0 or 1, and P₁ denotes a length of an outline of the target reference image, and
in Equation 2 above, C₂ denotes the second circularity, A₂ denotes a total area of pixels having the brightness value of 1 in the target inspection image including the pixels having the brightness value of 0 or 1, and P₂ denotes a length of an outline of the target inspection image.

3. The method of claim 1, further comprising: determining the mark to be defective when the area matching rate is less than a preset critical area matching rate or when the shape matching rate is less than a preset critical shape matching rate.

4. The method of claim 1, wherein, in the acquiring of the target reference image and the target inspection image, each of the target reference image and the target inspection image includes only pixels having a first brightness value or a second brightness value that is higher than the first brightness value.

5. The method of claim 1, wherein the calculating of the area matching rate includes equalizing a total number of pixels of the target reference image to a total number of pixels of the target inspection image.

6. The method of claim 1, wherein the calculating of the area matching rate includes:
equalizing a size of the target reference image to a size of the target inspection image; and
matching and overlapping a center of the target reference image with a center of the target inspection image.

7. The method of claim 1, wherein, in the acquiring of the target reference image and the target inspection image, each of the original reference image and the original inspection image includes a black and white image.

8. The method of claim 1, wherein the mark includes an identification mark engraved on a molding layer of the semiconductor package.

9. A method of inspecting a mark of a semiconductor package, the method comprising:
acquiring an original inspection image to determine whether the mark is defective;
acquiring an original reference image that is a reference for determining whether the mark is defective;
converting each of the original reference image and the original inspection image into a binary image through thresholding;
defining an outline of the original reference image, which was converted to the binary image, and an outline of the original inspection image, which was converted to the binary image;
acquiring a target reference image by partitioning the original reference image;
acquiring a target inspection image by extracting a part that corresponds to the target reference image from the original inspection image;
calculating an area matching rate by calculating a number of error pixels that have different brightness values from each other among pixels of the target reference image that correspond to pixels of the target inspection image, and by using the number of error pixels relative to a number of total pixels of the target reference image; and
calculating a shape matching rate by acquiring a first circularity of the target reference image and a second circularity of the target inspection image, and by comparing the first circularity with the second circularity.

10. The method of claim 9, wherein, in the defining of the outline, the original reference image includes a plurality of unit reference areas that are formed from dividing the original reference image with an outline as a boundary.

11. The method of claim 10, wherein, in the acquiring of the target reference image, the target reference image includes at least a part of one unit reference area among the plurality of unit reference areas.

12. The method of claim 9, further comprising:
after acquiring the target inspection image,
equalizing a pixels per inch (PPI) of the target inspection image to be equal to a PPI of the target reference image.

13. The method of claim 9, wherein the calculating of the area matching rate includes:
equalizing a size of the target reference image to a size of the target inspection image; and
matching and overlapping a center of the target reference image with a center of the target inspection image.

14. The method of claim 9, wherein,
in the defining of the outline of the original reference image that is converted to the binary image and the outline of the original inspection image that is converted to the binary image,
the original reference image that is converted to the binary image and the original inspection image that is converted to the binary image include only pixels having a first brightness value or a second brightness value that is higher than the first brightness value, and
the outline is a boundary between a pixel having the first brightness value and a pixel having the second brightness value.

15. The method of claim 14, wherein,
in the calculating of the area matching rate,
when a pixel of the target inspection image has the first brightness value, and a pixel of the target reference image, which corresponds to the pixel of the target inspection image, has the second brightness value, or
when the pixel of the target inspection image has the second brightness value, and the pixel of the target reference image, which corresponds to the pixel of the target inspection image, has the first brightness value,
the pixel of the target inspection image is determined to be an error pixel.

16. The method of claim 9, further comprising: determining the mark to be defective when the area matching rate is less than a preset critical area matching rate or when the shape matching rate is less than a preset critical shape matching rate.

17. A method of inspecting a mark of a semiconductor package, the method comprising:
acquiring an original inspection image to determine whether the mark engraved on a molding layer of the semiconductor package is defective;
acquiring an original reference image that is a reference for determining whether the mark is defective;
converting each of the original reference image and the original inspection image into a binary image through thresholding;
defining an outline of the original reference image, which was converted to the binary image, and an outline of the original inspection image, which was converted to the binary image, and configuring the original reference image as a plurality of unit reference areas formed from dividing the original reference image with an outline as a boundary;
acquiring a preliminary reference image comprising one unit reference area among the plurality of unit reference areas by partitioning the original reference image;
acquiring a preliminary inspection image by extracting a part corresponding to the preliminary reference image from the original inspection image;
acquiring a target reference image and a target inspection image by respectively dividing the preliminary reference image and the preliminary inspection image;
equalizing a pixels per inch (PPI) of the target reference image to be equal to a PPI of the target inspection image, and equalizing a size of the target reference image to a size of the target inspection image;
calculating an area matching rate by calculating a number of error pixels that have different brightness values from each other among pixels of the target reference image that correspond to pixels of the target inspection image, and by using the number of error pixels relative to a number of total pixels of the target reference image; and
calculating a shape matching rate by acquiring a first circularity of the target reference image and a second circularity of the target inspection image, and by comparing the first circularity with the second circularity.

18. The method of claim 17, wherein,
in the defining of the outline of the original reference image, which is converted to the binary image, and the outline of the original inspection image, which is converted to the binary image,
the original reference image, which is converted to the binary image, and the original inspection image, which is converted to the binary image, include only pixels having a first brightness value or a second brightness value that is higher than the first brightness value, and the outline is a boundary between a pixel having the first brightness value and a pixel having the second brightness value.

19. The method of claim 17, wherein,
in the acquiring of the target reference image and the target inspection image,
the target reference image is one of four areas in a quadrant that is divided with respect to a center of the preliminary reference image, and
the target inspection image is one of four areas in a quadrant that is divided with respect to a center of the preliminary inspection image, and corresponds to the target reference image.

20. The method of claim 17, wherein,
in the calculating of the first circularity and the second circularity,
the first circularity is determined by performing an operation according to Equation 1 below, and the second circularity is determined by performing an operation according to Equation 2 below,
$${C}_{1} = 4 π \times \frac{{A}_{1}}{{P}_{1}^{2}} \qquad [ Equation 1 ]$$
$${C}_{2} = 4 π \times \frac{{A}_{2}}{{P}_{2}^{2}} \qquad [ Equation 2 ]$$
in Equation 1 above, C₁ denotes the first circularity, A₁ denotes a total area of pixels having a high brightness value of the target reference image, and P₁ denotes a length of an outline of the target reference image, and
in Equation 2 above, C₂ denotes the second circularity, A₂ denotes a total area of pixels having a high brightness values of the target inspection image, and P₂ denotes a length of an outline of the target inspection image.
